(19) United States
(12) Patent Application Publication
(10) Pub. No.: US 2008/0233702 A1
(43) Pub. Date: Sep. 25, 2008

(54) Method of forming a recess in a semiconductor structure

(75) Inventor: Manoj Mehrotra, Plano, TX (US)

Correspondence Address: TEXAS INSTRUMENTS INCORPORATED, P O BOX 655474, M/S 3999, DALLAS, TX, 75265, US

(73) Assignee: Texas Instruments Inc.

(21) Appl. No.: 11/726,684

(22) Filed: Mar. 22, 2007

(51) Int. Cl. H01L 21/336; H01L 21/461

(52) U.S. Cl. 438/303; 438/705; 257/E21.483; 257/E21.409

(57) ABSTRACT

One embodiment of the present invention relates to a method of processing a semiconductor device. During the method an amorphization implant is performed to amorphize a selected region of a semiconductor structure. The amorphized selected region is then removed by performing a recess etch that is selective thereto. Other methods and systems are also disclosed.

### FIELD OF INVENTION

The present invention relates generally to methods of manufacturing semiconductor devices and more particularly to method of forming a recess within a semiconductor structure.

### BACKGROUND OF THE INVENTION

A conventional MOS transistor generally includes a semiconductor substrate, such as silicon, having a source, a drain, and a channel positioned between the source and drain. A gate stack composed of a conductive material (a gate conductor), an oxide layer (a gate oxide), and sidewall spacers, is typically located above the channel. The gate oxide is typically located directly above the channel, while the gate conductor, generally comprised of polycrystalline silicon (polysilicon) material, is located above the gate oxide. The sidewall spacers protect the sidewalls of the gate conductor.

Generally, for a given electric field across the channel of a MOS transistor, the amount of current that flows through the channel is directly proportional to a mobility of carriers in the channel. Thus the higher the mobility of the carriers in the channel, the more current can flow and the faster a circuit can perform when using high mobility MOS transistors. One way to increase the mobility of the carriers in the channel of an MOS transistor is to produce a mechanical stress in the channel.

A compressive strained channel has significant hole mobility enhancement over conventional devices. A tensile strained channel, such as a thin silicon channel layer grown on relaxed silicon-germanium, achieves significant electron mobility enhancement. The most common method of introducing tensile strain in a silicon channel region is to epitaxially grow the silicon channel layer on a relaxed silicon-germanium (SiGe), layer or substrate. The ability to form a relaxed SiGe layer is important in obtaining an overlying, epitaxially grown, silicon layer under biaxial tensile strain, however the attainment of the relaxed SiGe layer can be costly and difficult to achieve.

It would be advantageous to have a transistor device and method that effectively and reliably provides strain to the device in order to improve carrier mobility. Such devices and methods could also be applied to other technologies as well.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to the more detailed description that is presented later.

One embodiment of the present invention relates to a method of processing a semiconductor device. During the method an amorphization implant is performed to amorphize a selected region of a semiconductor structure. The amorphized selected region is then removed by performing a recess etch that is selective thereto.

The following description and annexed drawings set forth in detail certain illustrative aspects and implementations of the invention. These are indicative of but a few of the various ways in which the principles of the invention may be employed.

### BRIEF DESCRIPTION OF THE DRAWINGS

FIG. 1 is a flow chart illustrating a method according to aspects of the present invention;

FIG. 2 is a flow chart illustrating a method according to aspects of the present invention;

FIGS. 2A-2J are cross-sectional views of stages in a manufacturing method in accordance with aspects of the present invention; and

FIGS. 3A-3F are cross-sectional views of stages in another manufacturing method in accordance with aspects of the present invention.

### DETAILED DESCRIPTION OF THE INVENTION

One or more implementations of the present invention will now be described with reference to the attached drawings, wherein like reference numerals are used to refer to like elements throughout, and wherein the illustrated structures are not necessarily drawn to scale.

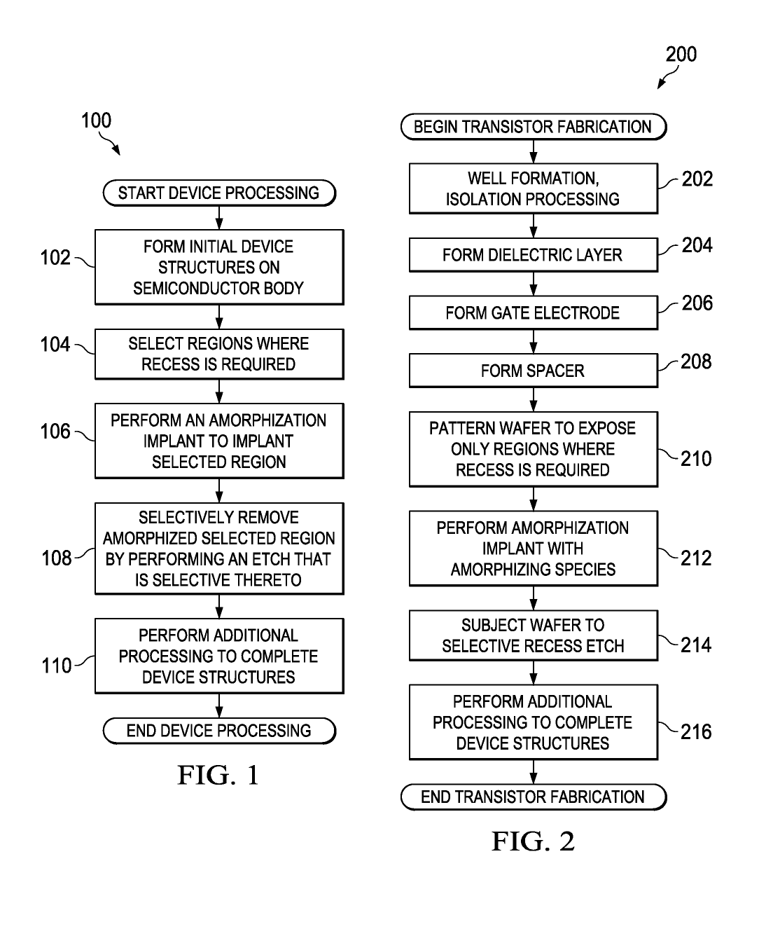

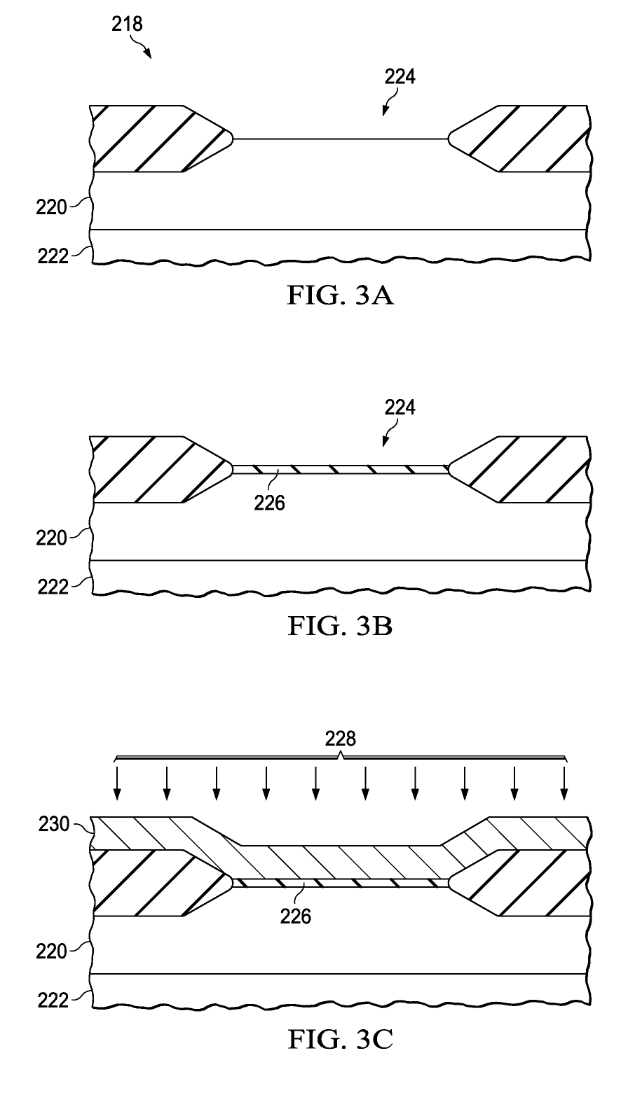

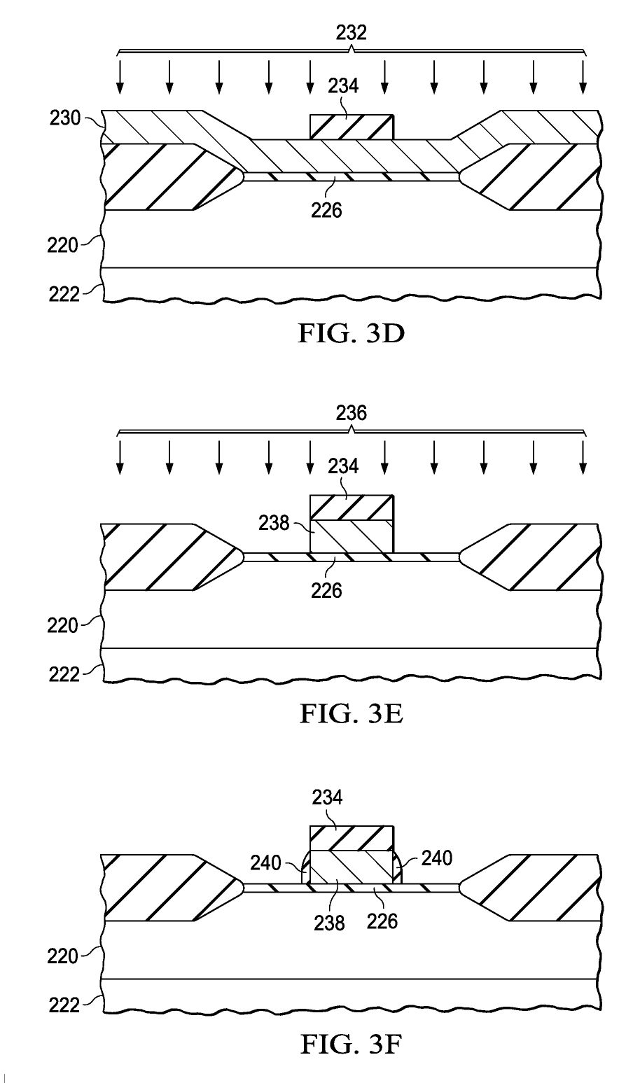

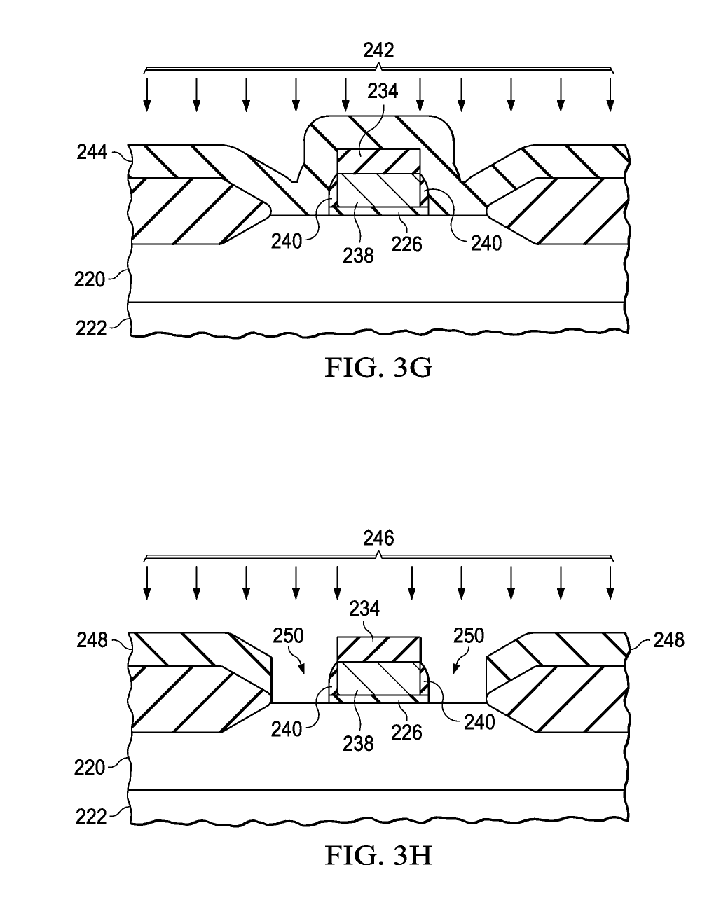

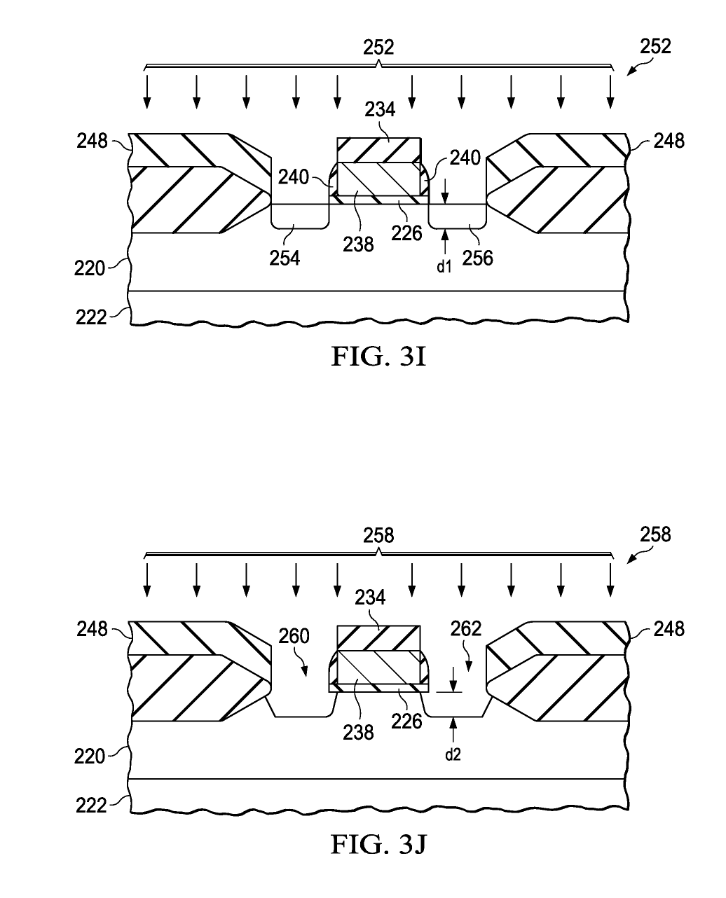

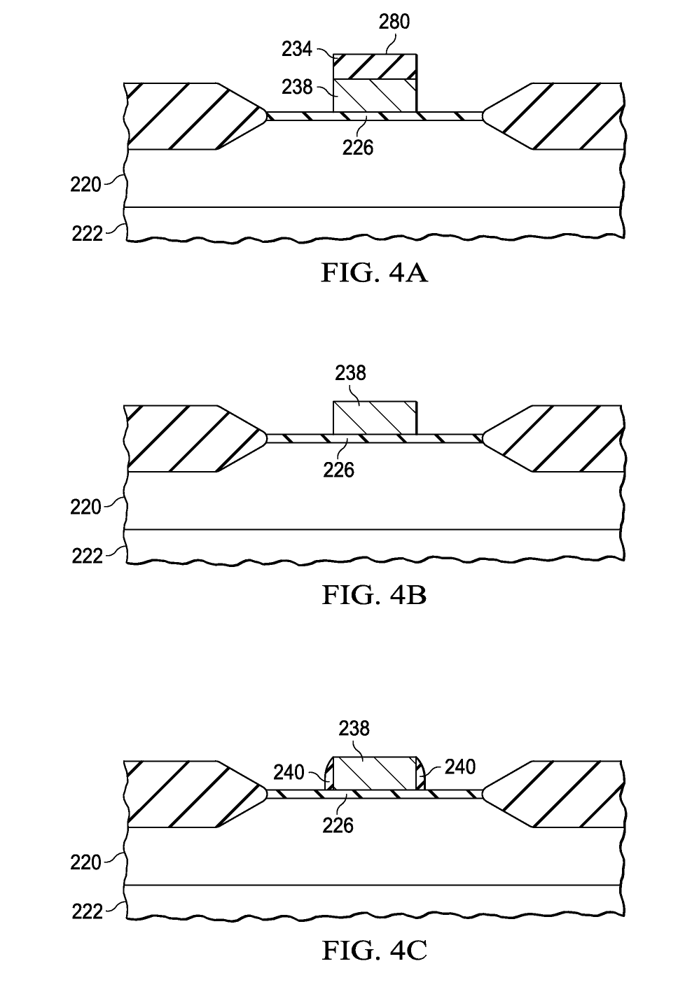

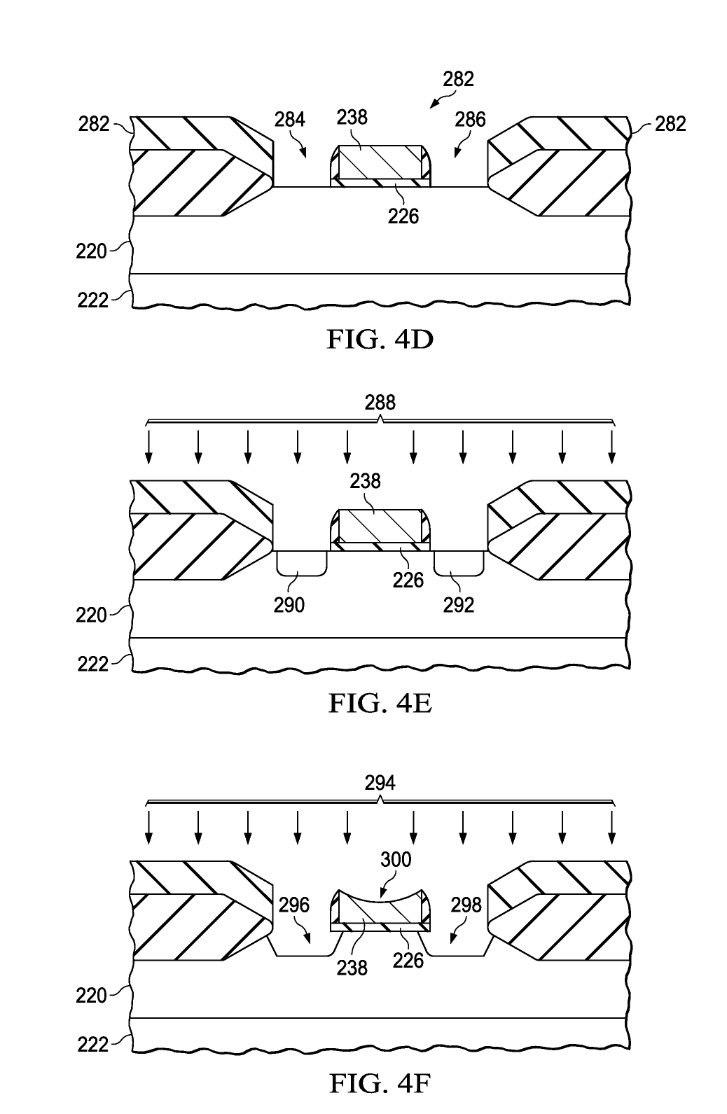

Due to the widespread commercial success of semiconductor devices, any improvement in manufacturing such devices is extremely valuable. Aspects of the present invention relate to methods of manufacturing semiconductor devices. For illustrative purposes, a general method 100 in accordance with aspects of the present invention is illustrated in FIG. 1, while more detailed implementations are described in FIG. 2, FIGS. 2A-2J, and FIGS. 3A-3F. While these methods are illustrated and described below as a series of acts or events, it will be appreciated that the present invention is not limited by the illustrated ordering of such acts or events. For example, some acts may occur in different orders and/or concurrently with other acts or events apart from those illustrated and/or described herein. In addition, not all illustrated steps may be required to implement a methodology in accordance with one or more aspects or embodiments of the present invention. Further, one or more of the acts depicted herein may be carried out in one or more separate acts and/or phases.

Referring now to FIG. 1, one can see a general method 100 for processing a semiconductor device in accordance with aspects of the present invention. At 102, a semiconductor structure is formed on a semiconductor body. Although an illustrative semiconductor structure that relates to a transistor is discussed further herein, it will be appreciated that the present invention relates to any type of semiconductor structure. Therefore, the term “semiconductor structure” could relate generally to any semiconductor device at any stage of manufacture. For example, the semiconductor structure could relate to any semiconductor layer or any insulating layer, and/or any pattern formed on such layers. Thus, the term could include semiconductor structures related to MOSFETs, BJTs, diodes, or any other semiconductor device.

After an initial semiconductor structure is formed, the method 100 proceeds to 104 where regions are selected in which a recess is required. In typical embodiments, this region can be selected by forming a mask over the structure, for example. The method 100 then proceeds to 106 and an amorphization implant is performed that amorphizes or damages the lattice of the selected region. Next, in 108, the amorphized selected region is removed by performing a recess etch (e.g., a wet etch or dry etch) that is selective to the amorphized region. This recess etch may create a recess in the semiconductor structure. In 110, after the recess is formed, further processing is performed to complete the desired semiconductor device. Although the following figures and associated description set forth more detailed descriptions of several embodiments of the present invention, it will be appreciated that these embodiments are just a few of a number of ways in which the invention could manifest itself.

Referring now to FIG. 2 and FIGS. 2A-2I, one can see a more detailed method 200 for forming a transistor in accordance with aspects of the present invention. More particularly, FIG. 2 shows a flowchart illustrating the method 200 while FIGS. 2A-2I show cross-sectional views of the transistor at various stages of the method. In the description that follows, the method 200 is briefly discussed with reference to FIG. 2, and then a more detailed discussion is included with reference to the cross-sectional views of FIGS. 2A-2J.

In FIG. 2, the method 200 begins at block 202 when a well (e.g., a p-well or n-well) is formed in a semiconductor body. Isolation structures, such as shallow-trench isolation structures may also be formed in the semiconductor body at this block. Next at 204, a dielectric (e.g., a gate oxide) is formed over the semiconductor body. In 206, a gate electrode is formed over the dielectric layer. At 208, spacers are formed so as to flank the gate electrode. At 212, the wafer is patterned to expose only regions where a recess is required. Then at 214, the wafer is implanted with an amorphizing species. In 216, the wafer is subjected to a recess etch that is selective to the amorphized selected region, thereby forming a recess in the semiconductor body. Thus, a typical recess etch removes only the amorphized material in the selected region, and substantially leaves other un-amorphized regions in place. After the recess etch has been performed, additional processing can be performed to complete the device structures in 216.

Referring now to FIG. 2A, one can see a semiconductor body 218 with several features. As shown, the semiconductor body 218 includes a p-well 220 formed over an n-type semiconductor substrate 222. In addition, two field oxide regions (FOX) are formed over sections of the p-well 220. An exposed p-well region 224, in which a transistor is to be formed, is located between the two field oxide regions. In one embodiment, the substrate 222 and p-well 220 comprise silicon and the FOX comprises silicon-dioxide.

In FIG. 2B, a dielectric 226 has been formed over the exposed p-well region 224. The dielectric 226 may also extend over the FOX regions. In one embodiment, the dielectric 226 could be silicon dioxide, although in other embodiments the dielectric could include a high-k dielectric. For example, high-k dielectrics could employ nitrogen, hafnium, or any number of materials to achieve a dielectric with a high dielectric constant (i.e., a high-k) relative to traditional silicon dioxide.

In FIG. 2C, a gate electrode layer is conformally deposited 228 over the existing structures. The gate electrode layer 230 typically comprises polysilicon, although other suitable materials could be used.

In FIG. 2D, a gate mask layer is conformally deposited 232 over the gate electrode layer 230. The gate mask layer is then patterned to form a gate mask 234. In typical embodiments the gate mask 234 can be patterned by photolithography techniques. In these and other embodiments, the gate mask 234 can comprise photoresist and/or an anti-reflective coating (e.g., IARC layer of SiN).

In FIG. 2E, a gate etch 236 is performed to pattern the gate electrode layer 230 to form a gate electrode 238. After the gate electrode 238 has been formed, a pair of spacers 240 can be formed and etched so as to flank the gate electrode 238, as shown in FIG. 2F. For example, the spacers 240 could be formed by oxide deposition followed by nitride, followed by an etch.

In FIG. 2G, an implant mask layer is conformally deposited 242 over the existing features. In one embodiment, the implant mask layer 244 comprises photoresist. In other embodiments, a hard mask or other type of mask could be deposited.

In FIG. 2H, the implant mask layer 244 is optionally patterned 246 to form an implant mask 248. The implant mask 248 may be patterned to expose only selected regions 250 where a recess is desired. In typical embodiments, this patterning may be achieved by photolithography techniques. In addition, because of the relatively small size of the gate electrode, the implant mask 248 often will not extend over the gate electrode. In one embodiment, the implant mask corresponds to the source regions and drain regions of n-type regions of the semiconductor device. In another embodiment, the implant mask corresponds to the source regions and drain regions of p-type regions of the semiconductor device. Thus, the implant mask can be tailored to select the n-type devices or p-type devices, which may ultimately be used to alter the characteristics of the selected devices (e.g., by altering the stress on the channel region lattice and thus altering the carrier mobility of the selected devices).

In FIG. 2I, an amorphization implant 252 is performed. During this implant step, amophization species impact the selected regions 250 of the wafer, forming amorphized selected regions 254, 256 that extend into the body of the semiconductor. This amorphizing implant breaks the crystalline bonds between the atoms and the semiconductor lattice is then no longer crystalline. Because the implant mask 248 covers the unexposed regions, typically only the selected regions 250 receive the implant, along with perhaps the gate electrode region.

The amorphized selected regions 254, 256 may extend to a depth, d1, beneath the surface of the p-well. In various embodiments, the depth, d1, could range from approximately 100 A to approximately 500 A. Illustrative amorphizing species include, but are not limited to: In and Sb. In various embodiments, the implant could be performed at implant energies ranging from approximately 10 keV to approximately 100 keV and will depend on the implanted species.

In FIG. 2J, a recess etch 258 is performed to remove the amorphized selected regions, thereby forming recesses 260, 262. In one embodiment, the recess etch 258 is selective to the amorphized selected regions (i.e., the recess etch may differentiate between the damaged lattice regions in the amorphized selected regions and the undamaged lattice in the unselected regions—thereby removing the amorphized regions while leaving the unselected regions substantially in tact). In these and other embodiments, the recess etch 258 is a wet etch. For example, wet etch chemistries could include hot phosphoric acid or hydroflouric acid. The recesses 260, 262 may extend to a depth, d2, beneath the surface of the p-well. In various embodiments, the depth, d2, could range from approximately 100 A to approximately 500 A.

Depending on the etch chemistry employed, the implant mask 248 could be removed before or after the recess etch 258 is performed.

After the recess etch 258 has been performed and the implant mask 248 has been removed, additional processing could be performed to complete the transistor. For example, in one embodiment, the recesses 260, 262 could be filled with a stress inducing material via selective epitaxial deposition. In selective epitaxial deposition, the stress inducing material could be formed only in the recesses 260, 262. After the selective epitaxial deposition, a source and drain could be implanted into the semiconductor body substantially where the recesses existed. An anneal could then be performed. Next, a contact liner (e.g, a PMD (Pre-Metal Dielectric) liner) could be formed to induce stress in the channel region of the transistor. After formation of the PMD liner, additional backend processing could be performed, such as the formation of interconnects and the like.

Referring now to FIGS. 3A-3F, another embodiment is discussed where the gate mask is removed prior to the formation of spacers. FIG. 3A shows gate mask 234 under which a gate electrode 238 has been formed, which can substantially correspond to FIG. 2E (previously discussed). In FIG. 3B, the gate mask 234 is removed, exposing the top surface 280 of the gate electrode 238. Next, in FIG. 3C, the spacers 240 are formed. In FIG. 3D, the implant mask layer 282 is deposited and patterned over the features present to expose only selected regions 284, 286 and perhaps the top surface of the gate electrode. In FIG. 3E, an amorphization implant 288 is performed to form amorphized selected regions 290, 292 that extend into the body of the semiconductor as previously discussed. In FIG. 3F, a recess etch 294 is performed. As shown, the recess etch may remove the amorphized selected regions 290, 292 as well as portions of the gate electrode, thereby forming recesses 296, 298, and 300 in the semiconductor device. Additional processing may be performed as previously discussed, to complete the transistors.

While the invention has been illustrated and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and the claims, such terms are intended to be inclusive in a manner similar to the term “comprising”.

What is claimed is:

1. A method of processing a semiconductor device, comprising:
performing an amorphization implant to amorphize a selected region of a semiconductor structure; and
selectively removing the amorphized selected region by performing a recess etch that is selective thereto.

2. The method of claim 1, where performing the recess etch comprises performing a wet etch.

3. The method of claim 1, further comprising:
prior to performing the amophization implant, forming an implant mask over the semiconductor structure to expose only the selected region.

4. The method of claim 3, where the implant mask comprises photoresist.

5. The method of claim 1, where the semiconductor structure is a semiconductor body on which the semiconductor device is formed.

6. The method of claim 5, where the selected region is associated with a source or drain region of the semiconductor device.

7. A method of processing a semiconductor device, comprising:
forming an initial device structure over a semiconductor body;
performing an amorphization implant to amorphize a selected region of the initial device structure;
performing a wet recess etch to remove the amorphized selected region of the initial device structure.

8. The method of claim 7, where the initial device structure comprises:
a dielectric formed over the semiconductor body;
a gate electrode suitably positioned over the dielectric;
spacers positioned over the dielectric and which flank the gate electrode.

9. The method of claim 8, where the selected region is laterally disposed from at least one of the spacers relative to the gate electrode.

10. The method of claim 8, further comprising:
prior to performing the amorphization implant, forming a gate mask over a semiconductor layer from which the gate electrode is formed.

11. The method of claim 10, further comprising:
prior to utilizing the amophization implant, forming an implant mask over the semiconductor layer to expose only the selected region.

12. A method of processing a semiconductor device, comprising:
forming an initial device structure over a semiconductor body;
forming an implant mask to expose a selected region of the initial device structure;
performing an amorphization implant to amorphize the selected region;
performing a selective recess etch to remove the amorphized selected region of the initial device structure, thereby forming a recess.

13. The method of claim 12, further comprising:
prior to performing the amorphization implant, forming a gate mask over a semiconductor layer from which a gate electrode of the initial device structure is formed.

14. The method of claim 13, where the implant mask is formed over the gate mask.

15. The method of claim 13, where the gate mask is removed prior to the formation of the implant mask.

16. The method of claim 12, where the implant mask comprises photoresist.

17. The method of claim 12, where the implant mask defines the selected region to relate to a source or drain of the semiconductor device.

18. The method of claim 12, further comprising:
filling the recess with stress inducing material via selective epitaxial deposition.

19. The method of claim 18, further comprising:
implanting a source and drain into the semiconductor body after filling the recess.

20. The method of claim 12, where the selective recess etch is a wet etch.
